(19) United States
(12) Patent Application Publication
(10) Pub. No.: US 2024/0237505 A1
(43) Pub. Date: Jul. 11, 2024

(54) ORGANIC ELECTROLUMINESCENT DEVICES

(71) Applicant: Universal Display Corporation, Ewing, NJ (US)

(72) Inventors: Seckin Gokaltun, Dresher, PA (US); Gregory McGraw, Yardley, PA (US); William E. Quinn, Whitehouse Station, NJ (US); Craig Anthony Outten, Rydal, PA (US); Jeff HAWTHORNE, Palo Alto, CA (US)

(21) Appl. No.: 18/544,876

(22) Filed: Dec. 19, 2023

Related U.S. Application Data
(60) Provisional application No. 63/437,174, filed on Jan. 5, 2023.

(51) Int. Cl. H10K 71/00; B23K 26/064; B23K 26/16; B23K 26/36; H10K 71/16

(52) U.S. Cl. CPC H10K 71/811; B23K 26/064; B23K 26/16; B23K 26/36; H10K 71/162

(57) ABSTRACT

Embodiments of the disclosed subject matter provide a laser source configured to output a laser beam, a beam transfer cavity to receive the outputted laser beam on a first side of the apparatus and output the laser beam on a second side of the apparatus, wherein the first side is opposite the second side, and a plume removal device having an exhaust aperture on the second side of the apparatus facing a heat affected zone (HAZ). A bottom surface of the plume removal device may be facing the substrate, where organic matter is disposed on the substrate, and the HAZ may be aligned with the surface of the substrate having the organic matter to be ablated by the laser beam.

### CROSS-REFERENCE TO RELATED APPLICATIONS

This application claims priority to U.S. patent application Ser. No. 63/437,174, filed Jan. 5, 2023, the entire contents of which are incorporated herein by reference.

### FIELD

The present invention relates to an apparatus to remove a deposited organic layer to achieve cleanliness for an encapsulation process without causing re-deposition of ablated material on the substrate, and techniques for using the same.

### BACKGROUND

Opto-electronic devices that make use of organic materials are becoming increasingly desirable for a number of reasons. Many of the materials used to make such devices are relatively inexpensive, so organic opto-electronic devices have the potential for cost advantages over inorganic devices. In addition, the inherent properties of organic materials, such as their flexibility, may make them well suited for particular applications such as fabrication on a flexible substrate. Examples of organic opto-electronic devices include organic light emitting diodes/devices (OLEDs), organic phototransistors, organic photovoltaic cells, and organic photodetectors. For OLEDs, the organic materials may have performance advantages over conventional materials. For example, the wavelength at which an organic emissive layer emits light may generally be readily tuned with appropriate dopants.

OLEDs make use of thin organic films that emit light when voltage is applied across the device. OLEDs are becoming an increasingly interesting technology for use in applications such as flat panel displays, illumination, and backlighting. Several OLED materials and configurations are described in U.S. Pat. Nos. 5,844,363, 6,303,238, and 5,707,745, which are incorporated herein by reference in their entirety.

One application for phosphorescent emissive molecules is a full color display. Industry standards for such a display call for pixels adapted to emit particular colors, referred to as “saturated” colors. In particular, these standards call for saturated red, green, and blue pixels. Alternatively the OLED can be designed to emit white light. In conventional liquid crystal displays emission from a white backlight is filtered using absorption filters to produce red, green and blue emission. The same technique can also be used with OLEDs. The white OLED can be either a single EML device or a stack structure. Color may be measured using CIE coordinates, which are well known to the art.

As used herein, the term “organic” includes polymeric materials as well as small molecule organic materials that may be used to fabricate organic opto-electronic devices. “Small molecule” refers to any organic material that is not a polymer, and “small molecules” may actually be quite large. Small molecules may include repeat units in some circumstances. For example, using a long chain alkyl group as a substituent does not remove a molecule from the “small molecule” class. Small molecules may also be incorporated into polymers, for example as a pendent group on a polymer backbone or as a part of the backbone. Small molecules may also serve as the core moiety of a dendrimer, which consists of a series of chemical shells built on the core moiety. The core moiety of a dendrimer may be a fluorescent or phosphorescent small molecule emitter. A dendrimer may be a “small molecule,” and it is believed that all dendrimers currently used in the field of OLEDs are small molecules.

As used herein, “top” means furthest away from the substrate, while “bottom” means closest to the substrate. Where a first layer is described as “disposed over” a second layer, the first layer is disposed further away from substrate. There may be other layers between the first and second layer, unless it is specified that the first layer is “in contact with” the second layer. For example, a cathode may be described as “disposed over” an anode, even though there are various organic layers in between.

As used herein, “solution processible” means capable of being dissolved, dispersed, or transported in and/or deposited from a liquid medium, either in solution or suspension form.

A ligand may be referred to as “photoactive” when it is believed that the ligand directly contributes to the photoactive properties of an emissive material. A ligand may be referred to as “ancillary” when it is believed that the ligand does not contribute to the photoactive properties of an emissive material, although an ancillary ligand may alter the properties of a photoactive ligand.

As used herein, and as would be generally understood by one skilled in the art, a first “Highest Occupied Molecular Orbital” (HOMO) or “Lowest Unoccupied Molecular Orbital” (LUMO) energy level is “greater than” or “higher than” a second HOMO or LUMO energy level if the first energy level is closer to the vacuum energy level. Since ionization potentials (IP) are measured as a negative energy relative to a vacuum level, a higher HOMO energy level corresponds to an IP having a smaller absolute value (an IP that is less negative). Similarly, a higher LUMO energy level corresponds to an electron affinity (EA) having a smaller absolute value (an EA that is less negative). On a conventional energy level diagram, with the vacuum level at the top, the LUMO energy level of a material is higher than the HOMO energy level of the same material. A “higher” HOMO or LUMO energy level appears closer to the top of such a diagram than a “lower” HOMO or LUMO energy level.

As used herein, and as would be generally understood by one skilled in the art, a first work function is “greater than” or “higher than” a second work function if the first work function has a higher absolute value. Because work functions are generally measured as negative numbers relative to vacuum level, this means that a “higher” work function is more negative. On a conventional energy level diagram, with the vacuum level at the top, a “higher” work function is illustrated as further away from the vacuum level in the downward direction. Thus, the definitions of HOMO and LUMO energy levels follow a different convention than work functions.

Layers, materials, regions, and devices may be described herein in reference to the color of light they emit. In general, as used herein, an emissive region that is described as producing a specific color of light may include one or more emissive layers disposed over each other in a stack.

As used herein, a “red” layer, material, region, or device refers to one that emits light in the range of about 580-700 nm or having a highest peak in its emission spectrum in that region. Similarly, a “green” layer, material, region, or device refers to one that emits or has an emission spectrum with a peak wavelength in the range of about 500-600 nm; a “blue” layer, material, or device refers to one that emits or has an emission spectrum with a peak wavelength in the range of about 400-500 nm; and a “yellow” layer, material, region, or device refers to one that has an emission spectrum with a peak wavelength in the range of about 540-600 nm. In some arrangements, separate regions, layers, materials, regions, or devices may provide separate “deep blue” and a “light blue” light. As used herein, in arrangements that provide separate “light blue” and “deep blue”, the “deep blue” component refers to one having a peak emission wavelength that is at least about 4 nm less than the peak emission wavelength of the “light blue” component. Typically, a “light blue” component has a peak emission wavelength in the range of about 465-500 nm, and a “deep blue” component has a peak emission wavelength in the range of about 400-470 nm, though these ranges may vary for some configurations. Similarly, a color altering layer refers to a layer that converts or modifies another color of light to light having a wavelength as specified for that color. For example, a “red” color filter refers to a filter that results in light having a wavelength in the range of about 580-700 nm. In general, there are two classes of color altering layers: color filters that modify a spectrum by removing unwanted wavelengths of light, and color changing layers that convert photons of higher energy to lower energy. A component “of a color” refers to a component that, when activated or used, produces or otherwise emits light having a particular color as previously described. For example, a “first emissive region of a first color” and a “second emissive region of a second color different than the first color” describes two emissive regions that, when activated within a device, emit two different colors as previously described.

As used herein, emissive materials, layers, and regions may be distinguished from one another and from other structures based upon light initially generated by the material, layer or region, as opposed to light eventually emitted by the same or a different structure. The initial light generation typically is the result of an energy level change resulting in emission of a photon. For example, an organic emissive material may initially generate blue light, which may be converted by a color filter, quantum dot or other structure to red or green light, such that a complete emissive stack or sub-pixel emits the red or green light. In this case the initial emissive material or layer may be referred to as a “blue” component, even though the sub-pixel is a “red” or “green” component.

In some cases, it may be preferable to describe the color of a component such as an emissive region, sub-pixel, color altering layer, or the like, in terms of 1931 CIE coordinates. For example, a yellow emissive material may have multiple peak emission wavelengths, one in or near an edge of the “green” region, and one within or near an edge of the “red” region as previously described. Accordingly, as used herein, each color term also corresponds to a shape in the 1931 CIE coordinate color space. The shape in 1931 CIE color space is constructed by following the locus between two color points and any additional interior points. For example, interior shape parameters for red, green, blue, and yellow may be defined as shown below:

| Color | CIE Shape Parameters |
|---|---|
| Central Red | Locus: [0.6270, 0.3725]; [0.7347, 0.2653]; |
| | Interior: [0.5086, 0.2657] |
| Central Green | Locus: [0.0326, 0.3530]; [0.3731, 0.6245]; |
| | Interior: [0.2268, 0.3321 |
| Central Blue | Locus: [0.1746, 0.0052]; [0.0326, 0.3530]; |
| | Interior: [0.2268, 0.3321] |
| Central Yellow | Locus: [0.373 l, 0.6245]; [0.6270, 0.3725]; |
| | Interior: [0.3 700, 0.4087]; [0.2886, 0.4572] |

More details on OLEDs, and the definitions described above, can be found in U.S. Pat. No. 7,279,704, which is incorporated herein by reference in its entirety.

### SUMMARY

According to an embodiment, an organic light emitting diode/device (OLED) is also provided. The OLED can include an anode, a cathode, and an organic layer, disposed between the anode and the cathode. According to an embodiment, the organic light emitting device is incorporated into one or more device selected from a consumer product, an electronic component module, and/or a lighting panel.

According to an embodiment, an apparatus may include a laser source configured to output a laser beam, a beam transfer cavity to receive the outputted laser beam on a first side of the apparatus and output the laser beam on a second side of the apparatus, where the first side is opposite the second side, and a plume removal device having an exhaust aperture on the second side of the apparatus facing a heat affected zone (HAZ).

According to an embodiment, an apparatus may include a laser source configured to output a laser beam, a beam transfer cavity to receive the outputted laser beam and output the laser beam towards a substrate, and a plume removal device having an exhaust aperture adjacent to a heat affected zone (HAZ) on the substrate and disposed at an initially predetermined distance from the substrate, where a bottom surface of the plume removal device is parallel to or facing the substrate, where organic matter is disposed on the substrate, and the HAZ is aligned with the surface of the substrate having the organic matter to be ablated by the laser beam.

The beam transfer cavity may be filled with an optically transparent material. The optically transparent material may be comprised of a sapphire material.

A feature of the organic material to be removed by ablation with the laser beam may be greater than or equal to 1 mm in size.

The apparatus may be disposed in a vacuum chamber having an inert gas at a pressure level that is controlled by a controller. The plume removal device may include an internal microchannel network configured to extract organic vapor formed from ablation by the laser beam with a flow of the inert gas of the chamber. The apparatus may include an exhaust source in fluid communication with an exhaust channel that is configured to remove the inert gas and ablated material from the chamber. The exhaust source may have a lower pressure than the chamber ambient. The plume removal device may be configured to have a radially incoming flow of the inert gas from the chamber towards an exit aperture of the plume removal device. The plume removal device may be disposed at the predetermined distance from the substrate and is configured to induce the flow of the inert gas of the chamber along a plane of the substrate.

The plume removal device may be formed from at least one of steel and/or aluminum.

The apparatus may include at least one heater configured to heat the plume removal device.

The apparatus may include a cold plate disposed over a stage configured to hold the substrate, where the cold plate includes window configured to allow the laser beam to pass through. The cold plate and the plume removal device may be mounted on the same frame that is disposed over and separate from the stage holding the substrate. The window may be a cut-out configured to allow the laser beam through, and is configured to allow the organic matter ablated by the laser beam to pass though towards the plume removal device.

The apparatus may include a heat shield disposed over a stage configured to hold the substrate, where the heat shield includes window configured to allow the laser beam to pass through. The window of the heat shield may be configured to allow the organic matter ablated by the laser beam to pass though towards the plume removal device. The heat shield and the plume removal device may be mounted on the same frame that is disposed over and separate from the stage holding the substrate. The window may include a cut-out configured to allow the laser beam through, and may be configured to allow the organic matter ablated by the laser beam to pass though towards the plume removal device.

The laser beam output by the laser may be configured to produce a pattern in the HAZ, and at least one pulse of the laser beam may have a diameter of 50-100 microns.

A fly height between a bottom surface of the plume removal device and the organic matter may be 50 μm to 1 mm.

The apparatus may include a sensor configured to detect changes in a surface height of the organic matter disposed on the substrate, and a controller to control a fly height between a bottom surface of the plume removal device and the organic matter based on the detected changes.

The substrate may be disposed on a stage, and the stage may be spaced apart from the laser source.

The substrate is disposed on a stage that is configured to be translated linearly at a predetermined rate. The laser, the beam transfer cavity, and the plume removal device may be configured to be movable in an opposite direction to the linear translation of the stage.

The substrate may be disposed on a stage, and the laser, the beam transfer cavity, and the plume removal device may be configured to be movable relative to the stage which is configured to be stationary.

The apparatus may include a plurality of channels that are connected to at least one exhaust aperture slot of the plume removal device.

The apparatus may include a plurality of channels that are connected to a plurality of exhaust aperture slots of the plume removal device, wherein the plurality of exhaust aperture slots is connected radially.

The substrate may have a first side and a second side, and the organic matter is disposed on the first side. The laser source may be spaced from the substrate to be closer to the second side of the substrate, and the plume removal device and the beam transfer cavity may be spaced from the substrate to be closer to the organic matter disposed on the first side of the substrate.

The substrate may have a first side and a second side, and the organic matter may be disposed on the first side. The plume removal device, the beam transfer cavity, and the laser source may be spaced from the substrate to be closer to the organic matter disposed on the first side of the substrate.

### BRIEF DESCRIPTION OF THE DRAWINGS

FIG. 1 shows an organic light emitting device.

FIG. 2 shows an inverted organic light emitting device that does not have a separate electron transport layer.

FIG. 3 shows a plume removal device according to an embodiment of the disclosed subject matter.

FIG. 4 shows example dimensions of the plume removal device used in a Computations Fluid Dynamics (CFD) study according to an embodiment of the disclosed subject matter.

FIG. 5 shows example boundary conditions in a CFD model according to an embodiment of the disclosed subject matter.

FIG. 6A shows time variation of a molar flow rate of organic vapor at the source and the exit according to an embodiment of the disclosed subject matter.

FIG. 6B shows an efficiency value when the flow rate of the organic vapor and a fly height are varied according to an embodiment of the disclosed subject matter.

FIG. 7 shows example images of plume transport at different times during the ablation process according to an embodiment of the disclosed subject matter.

FIG. 8 shows a substrate moving linearly that may be represented with a steady-state CFD model with a constant organic vapor source according to an embodiment of the disclosed subject matter.

FIG. 9 shows a cross-sectional view of the fluid domain with grayscale showing the vapor concentration and the arrows indicating the direction of the chamber gas and the vapor flux according to an embodiment of the disclosed subject matter.

FIG. 10 shows streamlines of vapor flux being removed from the source at various fly height values according to an embodiment of the disclosed subject matter.

FIG. 11 shows streamlines of vapor flux being removed from the source at various exhaust flow conditions according to an embodiment of the disclosed subject matter.

FIG. 12 shows example designs of a removal device with an outer manifold ring for flow uniformity according to embodiments of the disclosed subject matter.

FIG. 13 shows example designs with single and dual set of exhaust apertures according to embodiments of the disclosed subject matter.

FIG. 14 shows an example plume removal device with a radially outward delivery flow according to an embodiment of the disclosed subject matter.

FIGS. 15-16 show different views of an example plume removal device in a cross-flow configuration according to an embodiment of the disclosed subject matter.

FIGS. 17-18 show an example plume removal device that is similar to the plume removal device shown in FIG. 3, along with additional components, according to an embodiment of the disclosed subject matter.

FIG. 19 shows a laser thin film removal process to separate lines printed by OVJP into discrete pixels according to an embodiment of the disclosed subject matter.

FIG. 20 shows a plume removal system according to an embodiment of the disclosed subject matter.

### DETAILED DESCRIPTION

Generally, an OLED comprises at least one organic layer disposed between and electrically connected to an anode and a cathode. When a current is applied, the anode injects holes and the cathode injects electrons into the organic layer(s). The injected holes and electrons each migrate toward the oppositely charged electrode. When an electron and hole localize on the same molecule, an “exciton,” which is a localized electron-hole pair having an excited energy state, is formed. Light is emitted when the exciton relaxes via a photoemissive mechanism. In some cases, the exciton may be localized on an excimer or an exciplex. Non-radiative mechanisms, such as thermal relaxation, may also occur, but are generally considered undesirable.

The initial OLEDs used emissive molecules that emitted light from their singlet states (“fluorescence”) as disclosed, for example, in U.S. Pat. No. 4,769,292, which is incorporated by reference in its entirety. Fluorescent emission generally occurs in a time frame of less than 10 nanoseconds.

More recently, OLEDs having emissive materials that emit light from triplet states (“phosphorescence”) have been demonstrated. Baldo et al., “Highly Efficient Phosphorescent Emission from Organic Electroluminescent Devices,” Nature, vol. 395, 151-154, 1998; (“Baldo-I”) and Baldo et al., “Very high-efficiency green organic light-emitting devices based on electrophosphorescence,” Appl. Phys. Lett., vol. 75, No. 3, 4-6 (1999) (“Baldo-II”), are incorporated by reference in their entireties. Phosphorescence is described in more detail in U.S. Pat. No. 7,279,704 at cols. 5-6, which are incorporated by reference.

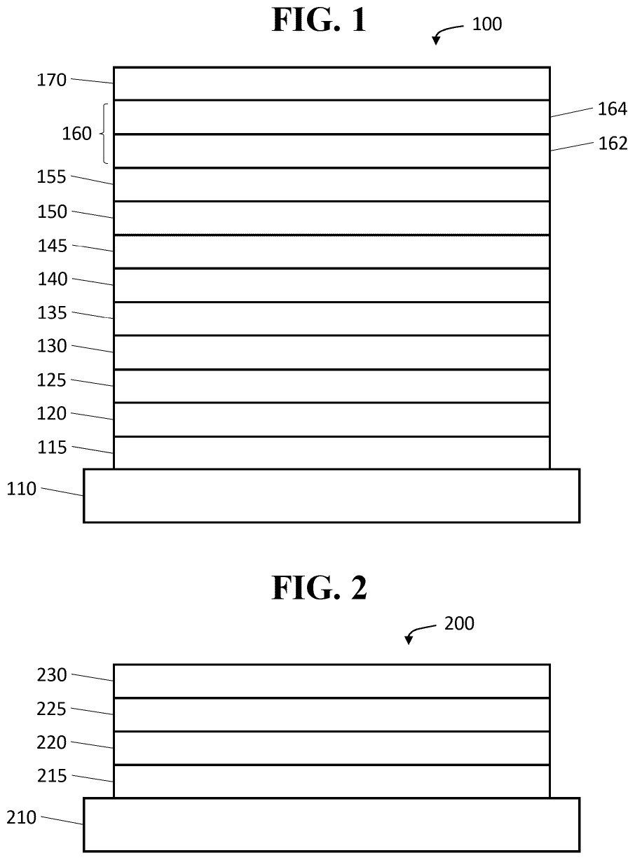

FIG. 1 shows an organic light emitting device 100. The figures are not necessarily drawn to scale. Device 100 may include a substrate 110, an anode 115, a hole injection layer 120, a hole transport layer 125, an electron blocking layer 130, an emissive layer 135, a hole blocking layer 140, an electron transport layer 145, an electron injection layer 150, a protective layer 155, a cathode 160, and a barrier layer 170. Cathode 160 is a compound cathode having a first conductive layer 162 and a second conductive layer 164. Device 100 may be fabricated by depositing the layers described, in order. The properties and functions of these various layers, as well as example materials, are described in more detail in U.S. Pat. No. 7,279,704 at cols. 6-10, which are incorporated by reference.

More examples for each of these layers are available. For example, a flexible and transparent substrate-anode combination is disclosed in U.S. Pat. No. 5,844,363, which is incorporated by reference in its entirety. An example of a p-doped hole transport layer is m-MTDATA doped with F4-TCNQ at a molar ratio of 50:1, as disclosed in U.S. Patent Application Publication No. 2003/0230980, which is incorporated by reference in its entirety. Examples of emissive and host materials are disclosed in U.S. Pat. No. 6,303,238 to Thompson et al., which is incorporated by reference in its entirety. An example of an n-doped electron transport layer is BPhen doped with Li at a molar ratio of 1:1, as disclosed in U.S. Patent Application Publication No. 2003/0230980, which is incorporated by reference in its entirety. U.S. Pat. Nos. 5,703,436 and 5,707,745, which are incorporated by reference in their entireties, disclose examples of cathodes including compound cathodes having a thin layer of metal such as Mg:Ag with an overlying transparent, electrically-conductive, sputter-deposited ITO layer. The theory and use of blocking layers is described in more detail in U.S. Pat. No. 6,097,147 and U.S. Patent Application Publication No. 2003/0230980, which are incorporated by reference in their entireties. Examples of injection layers are provided in U.S. Patent Application Publication No. 2004/0174116, which is incorporated by reference in its entirety. Barrier layer 170 may be a single- or multi-layer barrier and may cover or surround the other layers of the device. The barrier layer 170 may also surround the substrate 110, and/or it may be arranged between the substrate and the other layers of the device. The barrier also may be referred to as an encapsulant, encapsulation layer, protective layer, or permeation barrier, and typically provides protection against permeation by moisture, ambient air, and other similar materials through to the other layers of the device. Examples of barrier layer materials and structures are provided in U.S. Pat. Nos. 6,537,688, 6,597,111, 6,664,137, 6,835,950, 6,888,305, 6,888,307, 6,897,474, 7,187,119, and 7,683,534, each of which is incorporated by reference in its entirety.

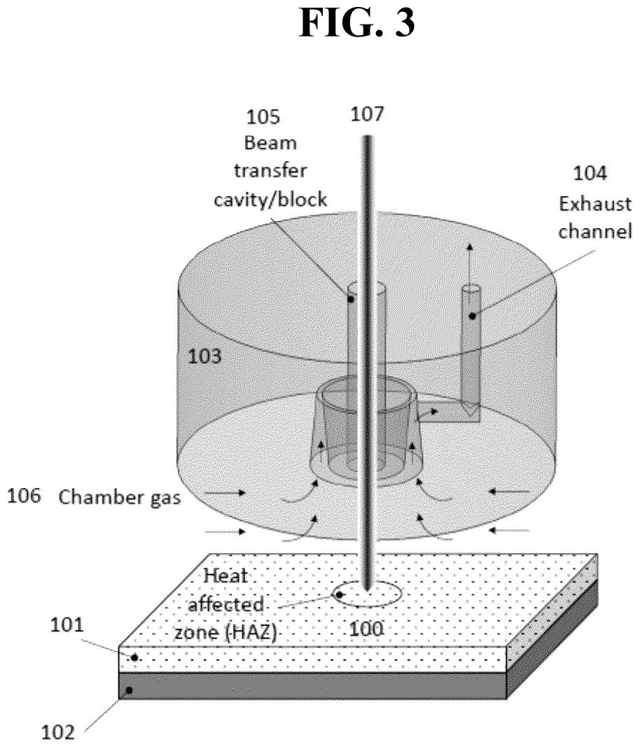

FIG. 2 shows an inverted OLED 200. The device includes a substrate 210, a cathode 215, an emissive layer 220, a hole transport layer 225, and an anode 230. Device 200 may be fabricated by depositing the layers described, in order. Because the most common OLED configuration has a cathode disposed over the anode, and device 200 has cathode 215 disposed under anode 230, device 200 may be referred to as an “inverted” OLED. Materials similar to those described with respect to device 100 may be used in the corresponding layers of device 200. FIG. 2 provides one example of how some layers may be omitted from the structure of device 100.

The simple layered structure illustrated in FIGS. 1 and 2 is provided by way of non-limiting example, and it is understood that embodiments of the invention may be used in connection with a wide variety of other structures. The specific materials and structures described are exemplary in nature, and other materials and structures may be used. Functional OLEDs may be achieved by combining the various layers described in different ways, or layers may be omitted entirely, based on design, performance, and cost factors. Other layers not specifically described may also be included. Materials other than those specifically described may be used. Although many of the examples provided herein describe various layers as comprising a single material, it is understood that combinations of materials, such as a mixture of host and dopant, or more generally a mixture, may be used. Also, the layers may have various sublayers. The names given to the various layers herein are not intended to be strictly limiting. For example, in device 200, hole transport layer 225 transports holes and injects holes into emissive layer 220, and may be described as a hole transport layer or a hole injection layer. In one embodiment, an OLED may be described as having an “organic layer” disposed between a cathode and an anode. This organic layer may comprise a single layer, or may further comprise multiple layers of different organic materials as described, for example, with respect to FIGS. 1 and 2.

Structures and materials not specifically described may also be used, such as OLEDs comprised of polymeric materials (PLEDs) such as disclosed in U.S. Pat. No. 5,247,190 to Friend et al., which is incorporated by reference in its entirety. By way of further example, OLEDs having a single organic layer may be used. OLEDs may be stacked, for example as described in U.S. Pat. No. 5,707,745 to Forrest et al, which is incorporated by reference in its entirety. The OLED structure may deviate from the simple layered structure illustrated in FIGS. 1 and 2. For example, the substrate may include an angled reflective surface to improve out-coupling, such as a mesa structure as described in U.S. Pat. No. 6,091,195 to Forrest et al., and/or a pit structure as described in U.S. Pat. No. 5,834,893 to Bulovic et al., which are incorporated by reference in their entireties.

In some embodiments disclosed herein, emissive layers or materials, such as emissive layer 135 and emissive layer 220 shown in FIGS. 1-2, respectively, may include quantum dots. An “emissive layer” or “emissive material” as disclosed herein may include an organic emissive material and/or an emissive material that contains quantum dots or equivalent structures, unless indicated to the contrary explicitly or by context according to the understanding of one of skill in the art. In general, an emissive layer includes emissive material within a host matrix. Such an emissive layer may include only a quantum dot material which converts light emitted by a separate emissive material or other emitter, or it may also include the separate emissive material or other emitter, or it may emit light itself directly from the application of an electric current. Similarly, a color altering layer, color filter, upconversion, or downconversion layer or structure may include a material containing quantum dots, though such layer may not be considered an “emissive layer” as disclosed herein. In general, an “emissive layer” or material is one that emits an initial light based on an injected electrical charge, where the initial light may be altered by another layer such as a color filter or other color altering layer that does not itself emit an initial light within the device, but may re-emit altered light of a different spectra content based upon absorption of the initial light emitted by the emissive layer and downconversion to a lower energy light emission. In some embodiments disclosed herein, the color altering layer, color filter, upconversion, and/or downconversion layer may be disposed outside of an OLED device, such as above or below an electrode of the OLED device.

Unless otherwise specified, any of the layers of the various embodiments may be deposited by any suitable method. For the organic layers, preferred methods include thermal evaporation, ink-jet, such as described in U.S. Pat. Nos. 6,013,982 and 6,087,196, which are incorporated by reference in their entireties, organic vapor phase deposition (OVPD), such as described in U.S. Pat. No. 6,337,102 to Forrest et al., which is incorporated by reference in its entirety, and deposition by organic vapor jet printing (OVJP), such as described in U.S. Pat. No. 7,431,968, which is incorporated by reference in its entirety. Other suitable deposition methods include spin coating and other solution-based processes. Solution based processes are preferably carried out in nitrogen or an inert atmosphere. For the other layers, preferred methods include thermal evaporation. Preferred patterning methods include deposition through a mask, cold welding such as described in U.S. Pat. Nos. 6,294,398 and 6,468,819, which are incorporated by reference in their entireties, and patterning associated with some of the deposition methods such as ink-jet and OVJD. Other methods may also be used. The materials to be deposited may be modified to make them compatible with a particular deposition method. For example, substituents such as alkyl and aryl groups, branched or unbranched, and preferably containing at least 3 carbons, may be used in small molecules to enhance their ability to undergo solution processing. Substituents having 20 carbons or more may be used, and 3-20 carbons is a preferred range. Materials with asymmetric structures may have better solution processibility than those having symmetric structures, because asymmetric materials may have a lower tendency to recrystallize. Dendrimer substituents may be used to enhance the ability of small molecules to undergo solution processing.

Devices fabricated in accordance with embodiments of the present invention may further optionally comprise a barrier layer. One purpose of the barrier layer is to protect the electrodes and organic layers from damaging exposure to harmful species in the environment including moisture, vapor and/or gases, etc. The barrier layer may be deposited over, under or next to a substrate, an electrode, or over any other parts of a device including an edge. The barrier layer may comprise a single layer, or multiple layers. The barrier layer may be formed by various known chemical vapor deposition techniques and may include compositions having a single phase as well as compositions having multiple phases. Any suitable material or combination of materials may be used for the barrier layer. The barrier layer may incorporate an inorganic or an organic compound or both. The preferred barrier layer comprises a mixture of a polymeric material and a non-polymeric material as described in U.S. Pat. No. 7,968,146, PCT Pat. Application Nos. PCT/US2007/023098 and PCT/US2009/042829, which are herein incorporated by reference in their entireties. To be considered a “mixture”, the aforesaid polymeric and non-polymeric materials comprising the barrier layer should be deposited under the same reaction conditions and/or at the same time. The weight ratio of polymeric to non-polymeric material may be in the range of 95:5 to 5:95. The polymeric material and the non-polymeric material may be created from the same precursor material. In one example, the mixture of a polymeric material and a non-polymeric material consists essentially of polymeric silicon and inorganic silicon.

In some embodiments, at least one of the anode, the cathode, or a new layer disposed over the organic emissive layer functions as an enhancement layer. The enhancement layer comprises a plasmonic material exhibiting surface plasmon resonance that non-radiatively couples to the emitter material and transfers excited state energy from the emitter material to non-radiative mode of surface plasmon polariton. The enhancement layer is provided no more than a threshold distance away from the organic emissive layer, wherein the emitter material has a total non-radiative decay rate constant and a total radiative decay rate constant due to the presence of the enhancement layer and the threshold distance is where the total non-radiative decay rate constant is equal to the total radiative decay rate constant. In some embodiments, the OLED further comprises an outcoupling layer. In some embodiments, the outcoupling layer is disposed over the enhancement layer on the opposite side of the organic emissive layer. In some embodiments, the outcoupling layer is disposed on opposite side of the emissive layer from the enhancement layer but still outcouples energy from the surface plasmon mode of the enhancement layer. The outcoupling layer scatters the energy from the surface plasmon polaritons. In some embodiments this energy is scattered as photons to free space. In other embodiments, the energy is scattered from the surface plasmon mode into other modes of the device such as but not limited to the organic waveguide mode, the substrate mode, or another waveguiding mode. If energy is scattered to the non-free space mode of the OLED other outcoupling schemes could be incorporated to extract that energy to free space. In some embodiments, one or more intervening layer can be disposed between the enhancement layer and the outcoupling layer. The examples for intervening layer(s) can be dielectric materials, including organic, inorganic, perovskites, oxides, and may include stacks and/or mixtures of these materials.

The enhancement layer modifies the effective properties of the medium in which the emitter material resides resulting in any or all of the following: a decreased rate of emission, a modification of emission line-shape, a change in emission intensity with angle, a change in the stability of the emitter material, a change in the efficiency of the OLED, and reduced efficiency roll-off of the OLED device. Placement of the enhancement layer on the cathode side, anode side, or on both sides results in OLED devices which take advantage of any of the above-mentioned effects. In addition to the specific functional layers mentioned herein and illustrated in the various OLED examples shown in the figures, the OLEDs according to the present disclosure may include any of the other functional layers often found in OLEDs.

The enhancement layer can be comprised of plasmonic materials, optically active metamaterials, or hyperbolic metamaterials. As used herein, a plasmonic material is a material in which the real part of the dielectric constant crosses zero in the visible or ultraviolet region of the electromagnetic spectrum. In some embodiments, the plasmonic material includes at least one metal. In such embodiments the metal may include at least one of Ag, Al, Au, Ir, Pt, Ni, Cu, W, Ta, Fe, Cr, Mg, Ga, Rh, Ti, Ru, Pd, In, Bi, Ca alloys or mixtures of these materials, and stacks of these materials. In general, a metamaterial is a medium composed of different materials where the medium as a whole acts differently than the sum of its material parts. In particular, we define optically active metamaterials as materials which have both negative permittivity and negative permeability. Hyperbolic metamaterials, on the other hand, are anisotropic media in which the permittivity or permeability are of different sign for different spatial directions. Optically active metamaterials and hyperbolic metamaterials are strictly distinguished from many other photonic structures such as Distributed Bragg Reflectors (“DBRs”) in that the medium should appear uniform in the direction of propagation on the length scale of the wavelength of light. Using terminology that one skilled in the art can understand: the dielectric constant of the metamaterials in the direction of propagation can be described with the effective medium approximation. Plasmonic materials and metamaterials provide methods for controlling the propagation of light that can enhance OLED performance in a number of ways.

In some embodiments, the enhancement layer is provided as a planar layer. In other embodiments, the enhancement layer has wavelength-sized features that are arranged periodically, quasi-periodically, or randomly, or sub-wavelength-sized features that are arranged periodically, quasi-periodically, or randomly. In some embodiments, the wavelength-sized features and the sub-wavelength-sized features have sharp edges.

In some embodiments, the outcoupling layer has wavelength-sized features that are arranged periodically, quasi-periodically, or randomly, or sub-wavelength-sized features that are arranged periodically, quasi-periodically, or randomly. In some embodiments, the outcoupling layer may be composed of a plurality of nanoparticles and in other embodiments the outcoupling layer is composed of a pluraility of nanoparticles disposed over a material. In these embodiments the outcoupling may be tunable by at least one of varying a size of the plurality of nanoparticles, varying a shape of the plurality of nanoparticles, changing a material of the plurality of nanoparticles, adjusting a thickness of the material, changing the refractive index of the material or an additional layer disposed on the plurality of nanoparticles, varying a thickness of the enhancement layer, and/or varying the material of the enhancement layer. The plurality of nanoparticles of the device may be formed from at least one of metal, dielectric material, semiconductor materials, an alloy of metal, a mixture of dielectric materials, a stack or layering of one or more materials, and/or a core of one type of material and that is coated with a shell of a different type of material. In some embodiments, the outcoupling layer is composed of at least metal nanoparticles wherein the metal is selected from the group consisting of Ag, Al, Au, Ir, Pt, Ni, Cu, W, Ta, Fe, Cr, Mg, Ga, Rh, Ti, Ru, Pd, In, Bi, Ca, alloys or mixtures of these materials, and stacks of these materials. The plurality of nanoparticles may have additional layer disposed over them. In some embodiments, the polarization of the emission can be tuned using the outcoupling layer. Varying the dimensionality and periodicity of the outcoupling layer can select a type of polarization that is preferentially outcoupled to air. In some embodiments the outcoupling layer also acts as an electrode of the device.

It is believed that the internal quantum efficiency (IQE) of fluorescent OLEDs can exceed the 25% spin statistics limit through delayed fluorescence. As used herein, there are two types of delayed fluorescence, i.e. P-type delayed fluorescence and E-type delayed fluorescence. P-type delayed fluorescence is generated from triplet-triplet annihilation (TTA).

On the other hand, E-type delayed fluorescence does not rely on the collision of two triplets, but rather on the thermal population between the triplet states and the singlet excited states. Compounds that are capable of generating E-type delayed fluorescence are required to have very small singlet-triplet gaps. Thermal energy can activate the transition from the triplet state back to the singlet state. This type of delayed fluorescence is also known as thermally activated delayed fluorescence (TADF). A distinctive feature of TADF is that the delayed component increases as temperature rises due to the increased thermal energy. If the reverse intersystem crossing rate is fast enough to minimize the non-radiative decay from the triplet state, the fraction of back populated singlet excited states can potentially reach 75%. The total singlet fraction can be 100%, far exceeding the spin statistics limit for electrically generated excitons.

E-type delayed fluorescence characteristics can be found in an exciplex system or in a single compound. Without being bound by theory, it is believed that E-type delayed fluorescence requires the luminescent material to have a small singlet-triplet energy gap (ΔES-T). Organic, non-metal containing, donor-acceptor luminescent materials may be able to achieve this. The emission in these materials is often characterized as a donor-acceptor charge-transfer (CT) type emission. The spatial separation of the HOMO and LUMO in these donor-acceptor type compounds often results in small ΔES-T. These states may involve CT states. Often, donor-acceptor luminescent materials are constructed by connecting an electron donor moiety such as amino- or carbazole-derivatives and an electron acceptor moiety such as N-containing six-membered aromatic ring.

Devices fabricated in accordance with embodiments of the invention can be incorporated into a wide variety of electronic component modules (or units) that can be incorporated into a variety of electronic products or intermediate components. Examples of such electronic products or intermediate components include display screens, lighting devices such as discrete light source devices or lighting panels, etc. that can be utilized by the end-user product manufacturers. Such electronic component modules can optionally include the driving electronics and/or power source(s). Devices fabricated in accordance with embodiments of the invention can be incorporated into a wide variety of consumer products that have one or more of the electronic component modules (or units) incorporated therein. A consumer product comprising an OLED that includes the compound of the present disclosure in the organic layer in the OLED is disclosed. Such consumer products would include any kind of products that include one or more light source(s) and/or one or more of some type of visual displays. Some examples of such consumer products include a flat panel display, a curved display, a computer monitor, a medical monitor, a television, a billboard, a light for interior or exterior illumination and/or signaling, a heads-up display, a fully or partially transparent display, a flexible display, a rollable display, a foldable display, a stretchable display, a laser printer, a telephone, a cell phone, tablet, a phablet, a personal digital assistant (PDA), a wearable device, a laptop computer, a digital camera, a camcorder, a viewfinder, a micro-display that is less than 2 inches diagonal, a 3-D display, a virtual reality or augmented reality display, a vehicle, a video walls comprising multiple displays tiled together, a theater or stadium screen, and a sign. Various control mechanisms may be used to control devices fabricated in accordance with the present invention, including passive matrix and active matrix. Many of the devices are intended for use in a temperature range comfortable to humans, such as 18 C to 30 C, and more preferably at room temperature (20-25 C), but could be used outside this temperature range, for example, from −40 C to 80 C.

The materials and structures described herein may have applications in devices other than OLEDs. For example, other optoelectronic devices such as organic solar cells and organic photodetectors may employ the materials and structures. More generally, organic devices, such as organic transistors, may employ the materials and structures.

In some embodiments, the OLED has one or more characteristics selected from the group consisting of being flexible, being rollable, being foldable, being stretchable, and being curved. In some embodiments, the OLED is transparent or semi-transparent. In some embodiments, the OLED further comprises a layer comprising carbon nanotubes.

In some embodiments, the OLED further comprises a layer comprising a delayed fluorescent emitter. In some embodiments, the OLED comprises a RGB pixel arrangement or white plus color filter pixel arrangement. In some embodiments, the OLED is a mobile device, a hand held device, or a wearable device. In some embodiments, the OLED is a display panel having less than 10 inch diagonal or 50 square inch area. In some embodiments, the OLED is a display panel having at least a 10 inch diagonal or 50 square inch area. In some embodiments, the OLED is a lighting panel.

In some embodiments of the emissive region, the emissive region further comprises a host.

In some embodiments, the compound can be an emissive dopant. In some embodiments, the compound can produce emissions via phosphorescence, fluorescence, thermally activated delayed fluorescence, i.e., TADF (also referred to as E-type delayed fluorescence), triplet-triplet annihilation, or combinations of these processes.

The OLED disclosed herein can be incorporated into one or more of a consumer product, an electronic component module, and a lighting panel. The organic layer can be an emissive layer and the compound can be an emissive dopant in some embodiments, while the compound can be a non-emissive dopant in other embodiments.

The organic layer can also include a host. In some embodiments, two or more hosts are preferred. In some embodiments, the hosts used maybe a) bipolar, b) electron transporting, c) hole transporting or d) wide band gap materials that play little role in charge transport. In some embodiments, the host can include a metal complex. The host can be an inorganic compound.

### Combination with Other Materials

The materials described herein as useful for a particular layer in an organic light emitting device may be used in combination with a wide variety of other materials present in the device. For example, emissive dopants disclosed herein may be used in conjunction with a wide variety of hosts, transport layers, blocking layers, injection layers, electrodes and other layers that may be present. The materials described or referred to below are non-limiting examples of materials that may be useful in combination with the compounds disclosed herein, and one of skill in the art can readily consult the literature to identify other materials that may be useful in combination.

Various materials may be used for the various emissive and non-emissive layers and arrangements disclosed herein. Examples of suitable materials are disclosed in U.S. Patent Application Publication No. 2017/0229663, which is incorporated by reference in its entirety.

### Conductivity Dopants:

A charge transport layer can be doped with conductivity dopants to substantially alter its density of charge carriers, which will in turn alter its conductivity. The conductivity is increased by generating charge carriers in the matrix material, and depending on the type of dopant, a change in the Fermi level of the semiconductor may also be achieved. Hole-transporting layer can be doped by p-type conductivity dopants and n-type conductivity dopants are used in the electron-transporting layer.

### HIL/HTL:

A hole injecting/transporting material to be used in the present invention is not particularly limited, and any compound may be used as long as the compound is typically used as a hole injecting/transporting material.

### EBL:

An electron blocking layer (EBL) may be used to reduce the number of electrons and/or excitons that leave the emissive layer. The presence of such a blocking layer in a device may result in substantially higher efficiencies, and or longer lifetime, as compared to a similar device lacking a blocking layer. Also, a blocking layer may be used to confine emission to a desired region of an OLED. In some embodiments, the EBL material has a higher LUMO (closer to the vacuum level) and/or higher triplet energy than the emitter closest to the EBL interface. In some embodiments, the EBL material has a higher LUMO (closer to the vacuum level) and or higher triplet energy than one or more of the hosts closest to the EBL interface. In one aspect, the compound used in EBL contains the same molecule or the same functional groups used as one of the hosts described below.

### Host:

The light emitting layer of the organic EL device of the present invention preferably contains at least a metal complex as light emitting material, and may contain a host material using the metal complex as a dopant material. Examples of the host material are not particularly limited, and any metal complexes or organic compounds may be used as long as the triplet energy of the host is larger than that of the dopant. Any host material may be used with any dopant so long as the triplet criteria is satisfied.

### HBL:

A hole blocking layer (HBL) may be used to reduce the number of holes and/or excitons that leave the emissive layer. The presence of such a blocking layer in a device may result in substantially higher efficiencies and/or longer lifetime as compared to a similar device lacking a blocking layer. Also, a blocking layer may be used to confine emission to a desired region of an OLED. In some embodiments, the HBL material has a lower HOMO (further from the vacuum level) and or higher triplet energy than the emitter closest to the HBL interface. In some embodiments, the HBL material has a lower HOMO (further from the vacuum level) and or higher triplet energy than one or more of the hosts closest to the HBL interface.

### ETL:

An electron transport layer (ETL) may include a material capable of transporting electrons. The electron transport layer may be intrinsic (undoped), or doped. Doping may be used to enhance conductivity. Examples of the ETL material are not particularly limited, and any metal complexes or organic compounds may be used as long as they are typically used to transport electrons.

### Charge Generation Layer (CGL)

In tandem or stacked OLEDs, the CGL plays an essential role in the performance, which is composed of an n-doped layer and a p-doped layer for injection of electrons and holes, respectively. Electrons and holes are supplied from the CGL and electrodes. The consumed electrons and holes in the CGL are refilled by the electrons and holes injected from the cathode and anode, respectively; then, the bipolar currents reach a steady state gradually. Typical CGL materials include n and p conductivity dopants used in the transport layers.

The manufacturing process of Organic Light-Emitting Diode (OLED) devices typically involves an encapsulation process. The encapsulation is used to protect the organic materials from oxygen, moisture, and other impurities by encapsulating the device within a barrier that is impenetrable to oxygen and water vapor. Various encapsulation methods have been developed for rigid and flexible substrates that utilize glass, metal, or polymer-based barrier materials. The sealing surface must be clean and free of contaminants for a successful encapsulation. This can become a challenge when the organic layers of OLEDs are produced using Organic Vapor Jet Printing (OVJP). OVJP prints rows of organic thin film features that align with subpixels on a substrate. The process requires a run-out margin at the beginning of each row for material deposition to stabilize, and a run-out margin at the end of each row for the row to terminate. This run-out margin may overlap with the encapsulation margin especially in narrow-bezel devices. OVJP may therefore deposit some organic vapor in the sealing area of the encapsulation margin. Embodiments of the disclosed subject matter provide a device that can remove the deposited organic layer to achieve cleanliness for the encapsulation process. Embodiments of the disclosed subject matter remove the organic deposited layer without causing re-deposition of ablated material on the substrate during the cleaning process.

OLED display technology introduces significant advantages compared to liquid-crystal-displays (LCDs) with wider viewing angle, higher brightness, and contrast ratios. However, the thin film layers in OLED displays typically need to be packaged properly to maintain the performance of OLED displays over a long lifetime of at least 10,000 hours. The OLED devices may be encapsulated to avoid the permeation of oxygen and air that can damage the organic materials used in the production of the devices. The encapsulation also avoids the permeation of oxygen and air to the cathode, which is the chemically reactive metal electrode layer in the OLED device. The sealing of the OLED devices by encapsulation has a target permeation value of less than 1×10⁻⁶ g/m²day for water vapor and 1×10⁻⁵ −1×10³ cm³/m² day for oxygen. These specifications are significantly more stringent than the sealing requirements for TFT and LCD technologies, that have water vapor transmission rate requirements of 1×10⁻³ g/m² day and 1×10⁻¹ g/m² day, respectively.

The encapsulation methods to achieve these target permeation values may vary depending on the substrate material used in the OLED displays. Rigid substrates are typically sealed using a glass or metal lid adhered with a low-permeation epoxy, whereas flexible displays typically use a thin-film permeation barrier having single or multiple organic and/or inorganic layers that are deposited onto the substrate using thin-film deposition methods such as sputtering, atomic layer deposition (ALD), plasma-enhanced chemical vapor deposition (PECVD), or the like.

Transmission of water vapor or oxygen through the encapsulation layers may occur at microdefects that can be formed during the deposition processes, imperfect interfaces between layers and the substrate, and gaps caused by entrapped particles in the sealing surface. The cleanliness and the surface roughness of the border of the display outside the active area may be configured to allow the UV-cured glass-frit adhesive to seal, and/or to avoid imperfections in the interfaces between the encapsulation layers that can cause sideways permeation. If sealing epoxy of a barrier lid is applied over OLED organic layers, water vapor and oxygen may diffuse through the organic material under the seal causing premature display failure.

The evaporation process typically used in the production of OLED displays involves deposition of light-emitting organic materials on the substrate in a vacuum chamber, where evaporated organic molecules are stenciled by thin metal masks placed over the active zone on the substrate. Although the fine openings in the thin metal masks may direct most of the organic material towards the specific areas on the grid, some organic molecules may deposit on the non-active outer border of the panel and cause undesired deposition in the sealing surfaces. For an OVJP deposition, the run-in and run-out areas of the deposited lines may interfere with sealing of the lid. It is desirable to eliminate any thin-film coating in the sealing zones to increase the effectiveness of the encapsulation.

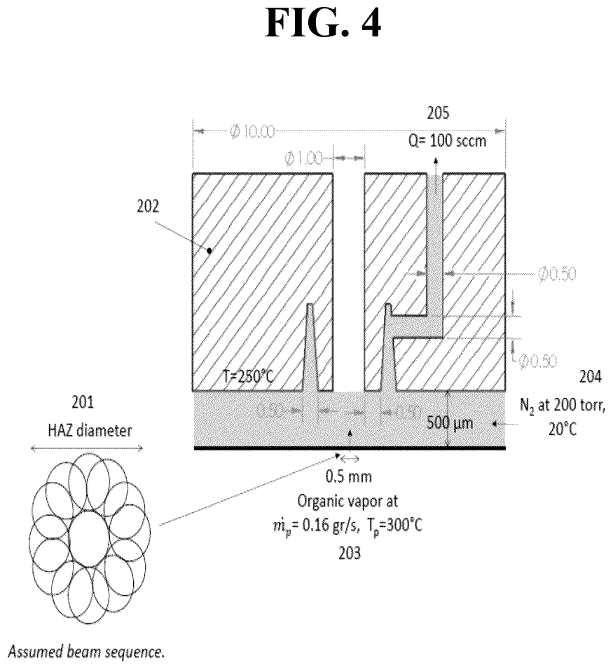

Embodiments of the disclosed subject matter provide a device that allows the transmission of a focused laser beam at the border section of the OLED displays and removes the plume of the organic material generated by laser ablation. An example plume removal device according to an embodiment of the disclose subject matter is shown in FIG. 3. The laser source providing the laser beam 107 may provide short or ultra-short pulses through a beam transfer cavity 105 at wavelengths that may correspond to the absorption properties of the organic material for optimum vapor production. This may be in the infrared or the ultraviolet band of the electromagnetic spectrum. The beam transfer cavity 105 may be either empty or filled with an optically transparent block. For example, the optically transparent block may be formed from a sapphire material. A plume removal device 103 is positioned away from a substrate 102 such that the bottom surface of the plume removal device 103 is parallel to or facing the substrate 102 and the center of a heat affected zone (HAZ) 100 is aligned with the surface where organic matter 101 is to be ablated. In an embodiment, the bottom surface of the plume removal device 103 faces the substrate in any orientation suitable for the removal of chamber gas 106 by exhaust channel 104. For example. The bottom surface may be substantially parallel or angled, so as not to be parallel, to the surface (i.e., the bottom surface is on an angle 0-90 degrees relative to the surface).

In an embodiment, the plume removal device 103 may be circular in shape, as shown. In alternative embodiments, the plume removal device 103 may be any shape. Additionally, as shown, the beam transfer cavity/block 105 is circular in shape. In alternative embodiments, the beam transfer cavity/block 105 may be any shape. In an embodiment, the overall shape of the beam transfer cavity/block 105 may be similar to the shape of the plume removal device 103. In an alterative embodiment, the beam transfer cavity/block 105 may be different to the shape of the plume removal device 103.

The ablation using the plume removal device 103 may take place in a vacuum chamber filled with an inert chamber gas 106 at a controlled pressure level. For example, the inert chamber gas 106 may be nitrogen, carbon dioxide, and/or argon, and/or any other gas known in the art. The plume removal device 103 may have an internally machined microchannel network that extracts the organic vapor created by ablation with the flow of the chamber gas. The organic vapor from the ablation may be removed from the chamber via exhaust piping connecting to an exhaust channel 104. The proximity of the bottom surface of the plume removal device 103 to the organic layer 101 on the substrate 102 may induce a sheet of chamber gas flow 106 along the plane of the substrate 102. The radially incoming flow of the chamber gas towards the exit aperture of the plume removal device 103 minimizes the escape of the organic vapor to the non-ablated section of the substrate 102 and avoids post-deposition by entrapping the plume created. The short-pulse laser creates a small HAZ area 100 in the organic layer 101, and heat conduction in the substrate 102 may be minimized. The plume removal device 103 may be machined out of aluminum or steel, and/or other suitable material with a low radiosity. The plume removal device 103 may be heated with external heaters to temperature levels higher than the sublimation temperature of the material being ablated to avoid clogging of the internal channels.

The plume removal device may be a device which extracts organic vapor created by ablation of the HAZ area of the substrate by the laser beam with the flow of the chamber gas. The plume removal device may be positioned apart from the substrate to induce a symmetric flow pattern in a gap it between the substrate and the plume removal device and may divert the flow uniformly towards an exhaust of the plume removal device. The plume removal device may be configured to allow the laser beam from the laser source to create an ablation pattern with minimal interaction with the created plume. The velocity of the carrier gas flow in the direction of the exhaust aperture of the plume removal device may be sufficient to capture material in the plume created by the ablation before it can redeposit on the surface of the substrate. The carrier gas flow and the exhaust flow may be a function of the exhaust pressure value attained, area of the exhaust aperture, and the distance between the substrate and lower surface of the plume removal device.

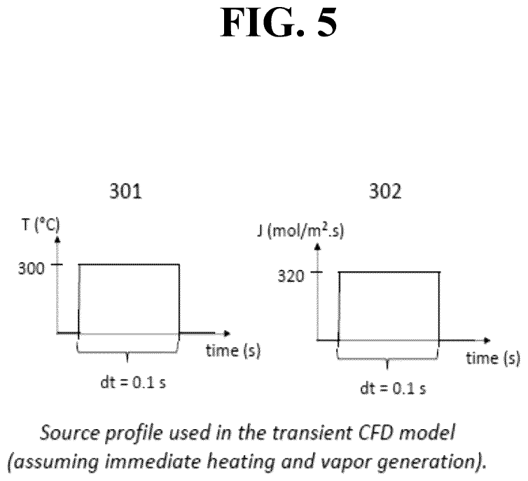

The plume removal process may be represented in a computer simulation using Computational Fluid Dynamics (CFD). The simulation may use a plume removal device 202 and corresponding dimensions as shown in FIG. 4. The laser beam may produce a circular HAZ pattern 201 of 0.5 mm diameter, with individual pulse diameters that may range between 50 to 100 microns. The organic vapor production at the HAZ pattern 201 on the organic layer 203 may be 0.16 g/s (grams per second), which may be a representative value for the evaporation rate at 300° C. These values may change, depending on the properties of a material. The exhaust pumping provided at outlet 205 of the plume removal device 202 may induce a flow rate of 100 sccm (standard cubic centimeters per minute). The temperature may be controlled to not fall below a sublimation temperature of the material being ablated. The incoming chamber gas 204 may be provided at 200 torr (chamber pressure) and 20° C. The distance between the bottom surface of the plume removal device 202 and the organic layer 203 may be referred to throughout as the Fly Height (FH). In this example, the fly heigh (FH) may be set 0.5 mm.

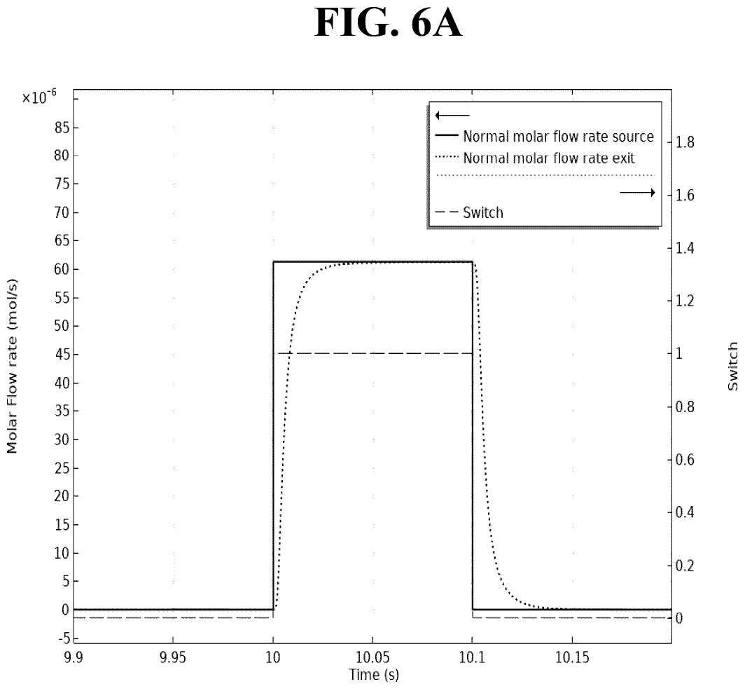

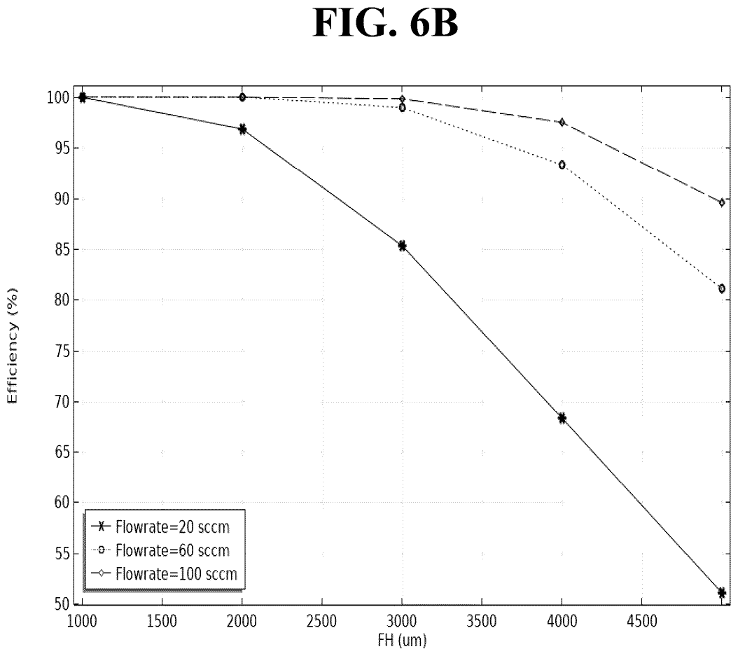

The laser ablation of the organic material in the HAZ may experience a temperature change 301 as shown in FIG. 5, which results in a molar flux 302 during the ablation duration of the laser, where dt=0.1 s, where dt is the change in time (seconds). FIG. 6A shows that the plume generation rate at the HAZ may follow a step change in time that corresponds to the profile of the laser pulse. The rate of vapor being removed at the outlet port of the device is observed after a short delay from the onset of the plume initiation. The amount of material removal at these conditions modeled in the CFD simulation shows that the plume removal device has an effectiveness of 99.9% in removing the vapor produced. In the example shown in FIG. 6A, the fly height may be 500 μm, mp (i.e., the rate of ablation) may be 0.16 g/s, Tp (i.e., the temperature of the ablated material) may be 300° C., Tw (i.e., temperature of the plume removal device) may be 250° C., and Q (i.e., the exhaust gas flow rate) may be 100 sccm. The organic vapor removal efficiency, as predicted by the CFD simulations, may vary with the exhaust gas flow rate, Q, maintained at a given fly height value, FH. Significantly high flow rates (Q>>100 sccm) may not be desirable, as it may result in undesired deposition of organic material in the internal channel walls of the device due to excessive cooling provided by the chamber gas. However, CFD simulations have indicated that 100% efficiency can be maintained even at low flowrates such as 60 sccm for FH<2 mm and even at 20 sccm at FH<1 mm, as shown in FIG. 6B.

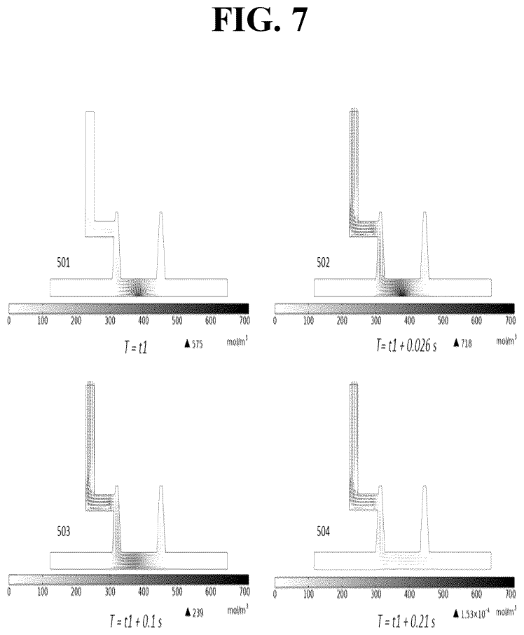

FIG. 7 shows a cross-sectional view of a flow domain between a plume removal device and an organic layer, as well as the internal flow passages 501-504. The concentration of the organic vapor is represented in grayscale colormap, and the arrows show the direction of the vapor flux. 501 corresponds to a time right after initiating the plume generation. 502 shows that the plume enters the exit apertures facing the vapor source and is biased towards the exit port direction. 503 shows the plume transport continues after the laser pulse is removed and the vapor production is stopped. 504 corresponds to the time period beyond the laser pulse period, with a majority of the flux transport occurring within the device internal channels.

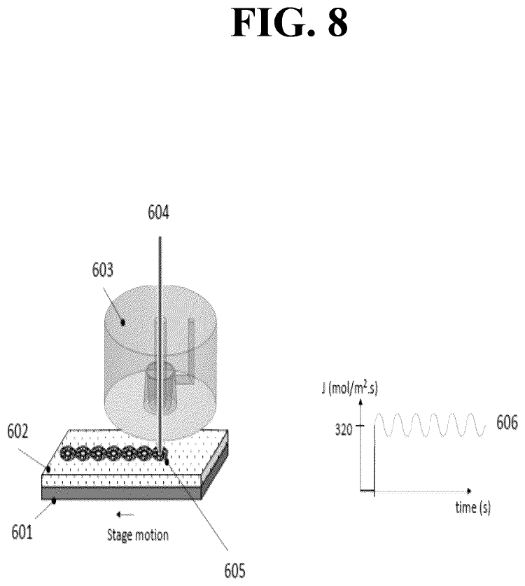

FIG. 8 shows a substrate 601 that may be translated linearly at a certain speed to create a sequence of HAZ sites 605 on the organic layer 602 of the substrate 601 while the laser source 604 follows a circular pattern to cover a larger area than the individual laser pulse diameter. This also may be achieved by moving the plume removal device 603 and the external laser source unit along the opposite direction of the stage carrying the substrate 601 while keeping the substrate stationary. With respect to the plume removal device 603, the heating and vapor production profile at the HAZ may follow a temporal pattern 606 that is approximated to be constant in time. Such conditions may be represented with a steady-state CFD simulation, where the vapor source may stay the same over time.

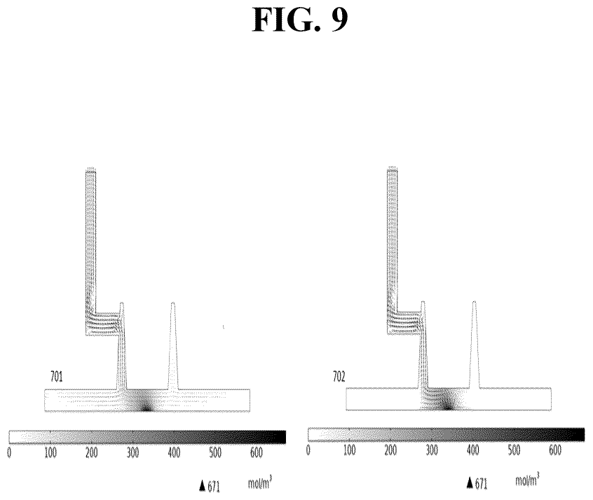

FIG. 9 shows the flow pattern of the chamber gas. 701 shows as nitrogen gas enters from the outer edges of the plume removal device and follows along the plane of the substrate and is exited vertically towards the outlet on the opposite end of the device. 702 shows a similar flux profile for the organic vapor as shown in 502 of FIG. 7 which is sustained during the period that covers the relative motion of the substrate with respect to the device. In FIG. 9, the fly height may be 500 μm, and Q may be 20 sccm.

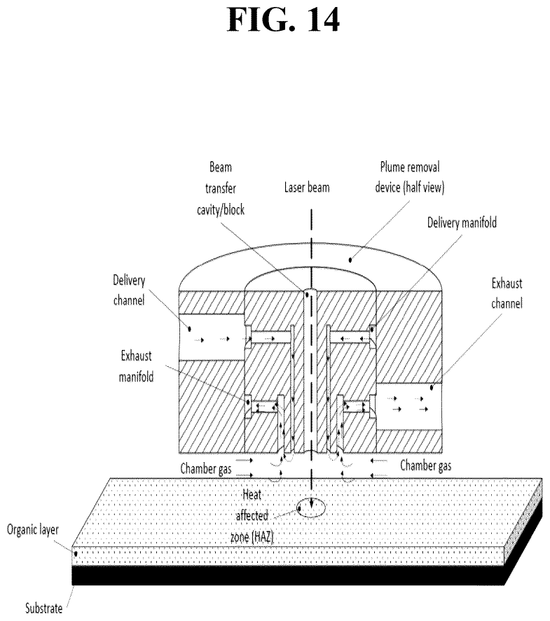

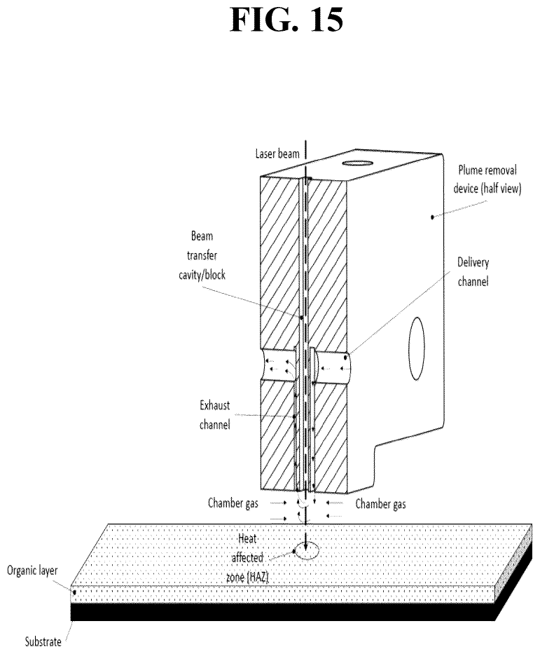

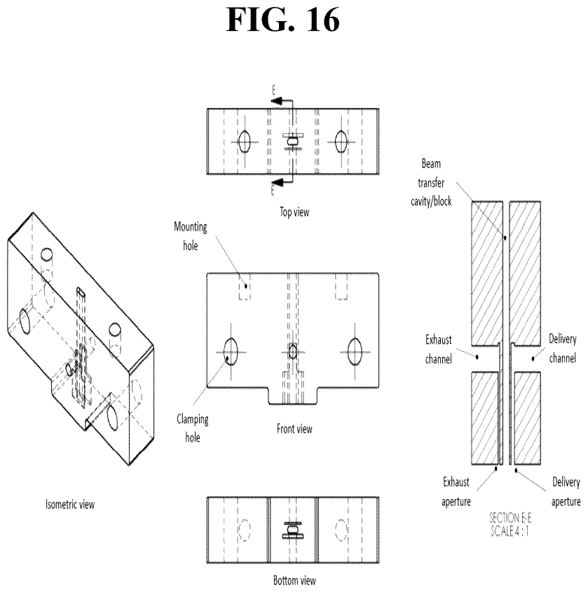

In some embodiments, the plume removal device may be a radially outward delivery flow device, where flow is from the center of the plume removal device and extends radially outward. For example, FIG. 14 shows a plume removal device similar to the plume removal device of FIG. 3, but with a radially outward delivery flow according to an embodiment of the disclosed subject matter. In other embodiments, the plume removal device may have a cross-flow configuration. For example, FIG. 15 shows a plume removal device with a cross-flow configuration, and FIG. 16 shows different views of a plume removal device having a cross-flow configuration. With the cross-flow configuration, the flow sweeps across the heat affected zone (HAZ) from the input to the exhaust.

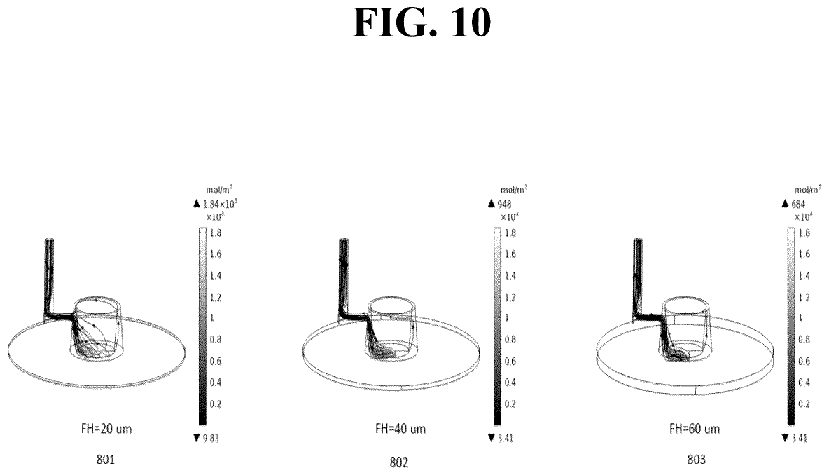

FIG. 10 shows fly height (FH) sensitivity, where the CFD analysis may be repeated for varying FH values ranging from 20 to 60 microns. 801 corresponds to the closest position of the plume removal device against the substrate with the highest concentration value at the source. 802 and 803 correspond to the cases where the device is raised to higher FH values, and lower vapor concentration is accumulated at the source. 801 indicates flow in the gap between the plume removal device and the substrate may be restricted and a minimum FH value is established based on the characteristics of the organic layer surface to be cleaned.

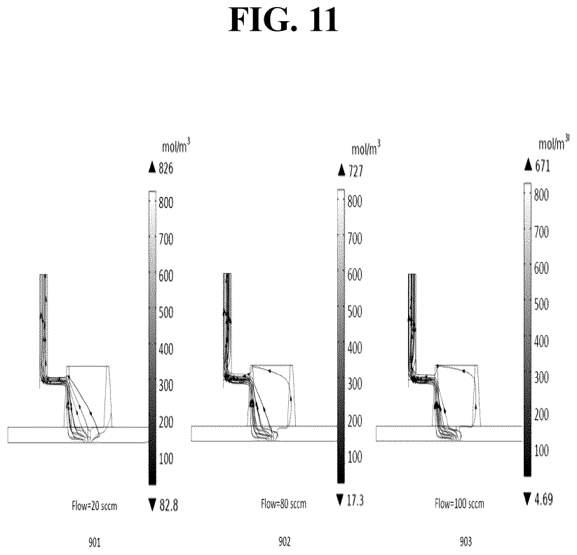

Similarly, the pumping at the outlet port of the plume removal device may be tailored to the material removal needs for a specific cleaning process. FIG. 11 shows the amount of flow rate created at the exhaust of the plume removal device may be insufficient to direct all the vapor flux generated at the ablated area 901. The minimum flow rate for capturing all the vapor produced without undesired post-deposition may be established similarly to the determination of the fly height of the plume removal device.

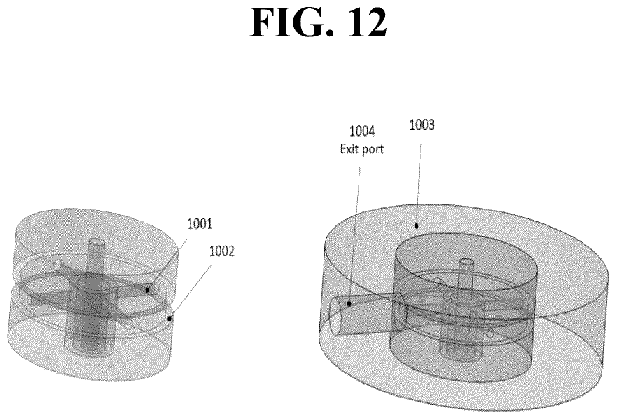

FIG. 12 shows another embodiment of the plume removal device with additional internal exit channels 1001, and with four channels connecting the exhaust aperture radially to a groove 1002 machined on the outer circumference of the plume removal device. When an outer ring 1003 is placed around the plume removal device, the groove 1002 may act as a manifold for the mixture of organic vapor and chamber gas and exit the assembly at a single outlet 1004. The outer ring 1003 may be used to mount the assembly to a frame that adjusts the relative position of the plume removal device with respect to the substrate. The optical equipment including the lenses, mirrors, and the laser source to transmit the laser beam through the device may be housed in the frame. In an alternative embodiment, there may be any number of internal exit channels.

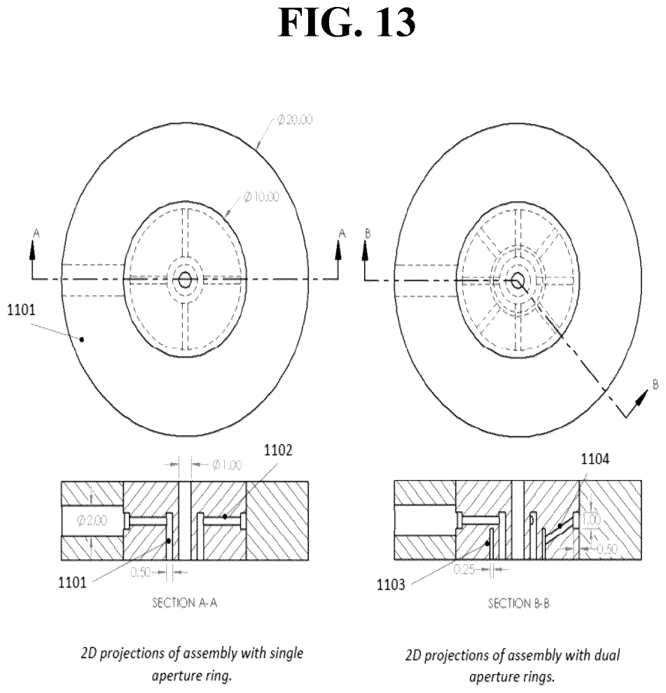

FIG. 13 shows cross-sectional view of the assembly utilizing four internal channels 1102 that connect to a single circular exhaust aperture slot 1101 of the device. Additional exhaust aperture slots 1103 may be machined around the inner aperture 1101 to capture any vapor that the inner aperture slot is unable to extract. The additional exhaust aperture slots may be connected radially to the outer groove with additional channels 1104. The number of internal channels could be selected based on the tact time requirements of the display manufacturing process to achieve a certain time duration for the cleaning process.

As shown in FIGS. 1-18, an apparatus may include a laser source configured to output a laser beam (e.g., laser beam 107 shown in FIG. 3 and/or laser beam 604 shown in FIG. 8), a beam transfer cavity (e.g., beam transfer cavity 105 shown in FIG. 3) to receive the outputted laser beam on a first side of the apparatus and output the laser beam on a second side of the apparatus, where the first side is opposite the second side, and a plume removal device having an exhaust aperture on the second side of the apparatus facing a heat affected zone (HAZ). As shown in FIGS. 1-18, an apparatus according to embodiments of the disclosed subject matter may include a laser source configured to output a laser beam (e.g., laser beam 107 shown in FIG. 3 and/or laser beam 604 shown in FIG. 8), and a beam transfer cavity (e.g., beam transfer cavity 105 shown in FIG. 3) to receive the outputted laser beam and output the laser beam towards a substrate (e.g., substrate 102 shown in FIG. 3 and/or substrate 601 shown in FIG. 8). The beam transfer cavity may be filled with an optically transparent material. The optically transparent material may be comprised of a sapphire material. In an embodiment, the beam transfer cavity 105 may be sized slightly larger than the size required for the laser beam 107. In other words, there may a small amount of space between the laser beam 107 and the beam transfer cavity/block 105. In this embodiment, in order to move the laser beam 107, and subsequently HAZ 100 over portions of the organic layer 101, the entire plume removal device 103 moves. In an alternative embodiment, the beam transfer cavity 105 may be sized much larger than the size required for the laser beam 107. In other words, there may be a large amount of space between the edge of the laser beam 107 and the edge of the beam transfer cavity/block 105. In this embodiment, in order to move the laser beam 107, and subsequently HAZ 100 over portion of the organic layer, only the laser beam 107 moves inside of the beam transfer cavity/block 105 while the remainder of the plume removal device 103 remain stationary relative to the laser beam 107. In yet another embodiment, both the plume removal device 103 and the laser beam 107 may be stationary and the substrate 102/organic layer 101 move relative to plume removal device 103 and the laser beam 107. In yet another embodiment, any combination of the previous embodiments may be used at the same time in order to orient the HAZ 100 over different portions of the organic layer 101.

In an embodiment, when the beam transfer cavity 105 is circular shaped the beam transfer cavity 105 has a diameter of 1 mm to 3 mm. In an embodiment, when the beam transfer cavity 105 is oval in shape, the short length of the oval may be between 1 mm to 3 mm and the long length of the oval may be between 1 mm and 3 mm. In an embodiment where the beam transfer cavity 105 is not circular, the beam transfer cavity 105 may have a minimum gap of 450 micron between the internal edge of the beam transfer cavity and laser beam 107.

The apparatus may include a plume removal device (e.g., plume removal device 103 shown in FIG. 3 and/or plume removal device 603 shown in FIG. 8) having an exhaust aperture adjacent to a heat affected zone (HAZ) (e.g., HAZ 100 shown in FIG. 3 and/or HAZ sites 605 shown in FIG. 8) on the substrate and disposed at an initially predetermined distance from the substrate, where a bottom surface of the plume removal device is parallel to or facing the substrate, where organic matter (e.g., organic layer 101 shown in FIG. 3 and/or organic layer 602 shown in FIG. 8) is disposed on the substrate, and the HAZ is aligned with the surface of the substrate having the organic matter to be ablated by the laser beam.

A feature of the organic material to be removed by ablation with the laser beam is greater than or equal to 1 mm in size. The laser beam output by the laser may be configured to produce a pattern in the HAZ, and at least one pulse of the laser beam may have a diameter of 50-100 microns. The pattern may be circular, linear, or the like. In an example circular pattern, the diameter may be 0.5 mm or any suitable size.

The apparatus may be disposed in a vacuum chamber (e.g., having an inert gas at a pressure level that is controlled by a controller). The vacuum chamber may have a pressure of 200 Torr and/or other suitable pressure. The vacuum chamber may include a chamber gas (e.g., chamber gas 106 shown in FIG. 3), which may be nitrogen. The vacuum chamber may be an oxygen-free and water-free environment. The plume removal device may include an internal microchannel network configured to extract organic vapor formed from ablation by the laser beam with a flow of the inert gas of the chamber. The apparatus may include an exhaust source in fluid communication with an exhaust channel (e.g., exhaust channel 104 shown in FIG. 3) that is configured to remove the inert gas and ablated material from the chamber. The exhaust source may have a lower pressure than the chamber ambient. The plume removal device may be configured to have a radially incoming flow of the inert gas from the chamber towards an exit aperture of the plume removal device. This configuration may be used to minimize the escape of the organic vapor to the non-ablated section of the substrate and entrap the plume. The plume removal device may be disposed at the predetermined distance from the substrate and may be configured to induce the flow of the inert gas of the chamber along a plane of the substrate. The plume removal device may be formed from steel, aluminum, and/or any other suitable material.

The organic plume removal device may have a different configuration for internal fluid flow channels, where a delivery channel as shown in FIG. 15 may introduce an inert gas into the chamber at a controlled delivery flow rate. The delivery gas may mix with the chamber gas and the organic vapor produced at the HAZ before they are captured by the exhaust channel of the device. The device may be maintained at a lower pressure than the chamber pressure corresponding to a controlled exhaust flow rate.

As the details of such a plume device configuration is shown in FIG. 16, the delivery and exhaust apertures may be in the form of rectangular slots rather than circular rings as was shown in previous configurations. The laser beam transfer cavity and/or block may be positioned between the delivery and exhaust slots in this configuration to create a unidirectional flow that crosses over the laser ablation zone. This may improve the organic vapor removal efficiency of the device as compared to other configurations that do not have delivery channels and apertures.

The substrate may be planar and may have variation in topography of the surface. The substrate may be disposed on a stage, and the stage may be spaced apart from the laser source. The substrate may be disposed on a stage that is configured to be translated linearly at a predetermined rate. The laser, the beam transfer cavity, and the plume removal device may be configured to be movable in an opposite direction to the linear translation of the stage. The substrate may be disposed on a stage, and the laser, the beam transfer cavity, and the plume removal device may be configured to be movable relative to the stage which may be configured to be stationary.

In some embodiments, the substrate may have a first side and a second side, and the organic matter is disposed on the first side. The laser source may be spaced from the substrate to be closer to the second side of the substrate, and the plume removal device and the beam transfer cavity may be spaced from the substrate to be closer to the organic matter disposed on the first side of the substrate. In some embodiments, the plume removal device, the beam transfer cavity, and the laser source may be spaced from the substrate to be closer to the organic matter disposed on the first side of the substrate.

A fly height between a bottom surface of the plume removal device and the organic layer may be 50 μm to 1 mm. The apparatus may include a sensor configured to detect changes in a surface height of the organic matter disposed on the substrate, and a controller to control the fly height between a bottom surface of the plume removal device and the organic layer based on the detected changes.

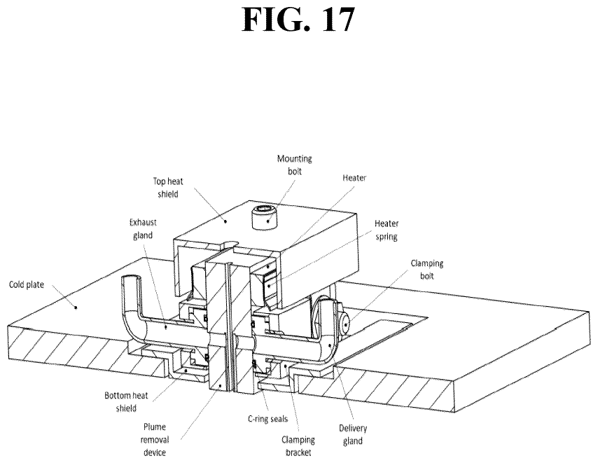

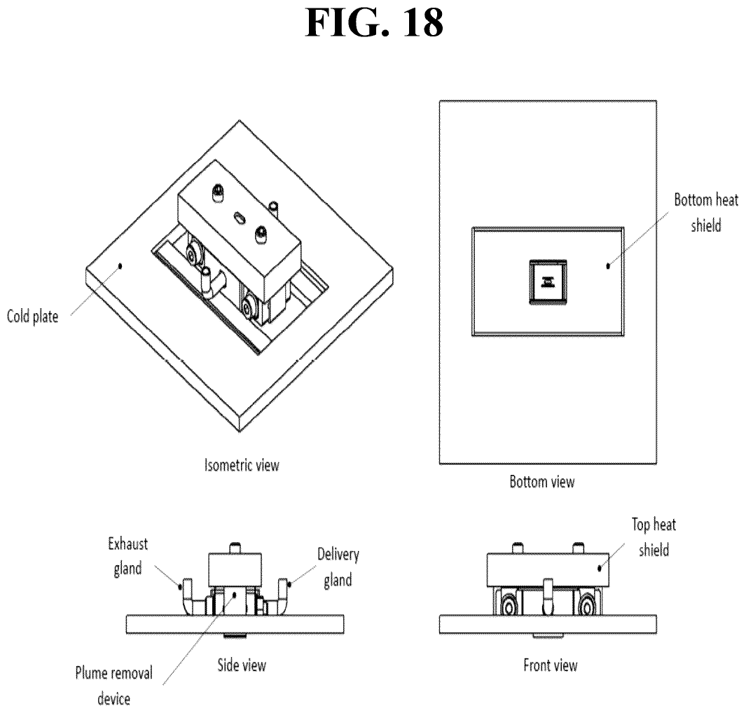

The apparatus may include at least one heater configured to heat the plume removal device. For example, FIG. 17 shows the plume removal device of the apparatus with a heater. The apparatus may include a cold plate disposed over the stage configured to hold the substrate, where the cold plate includes window configured to allow the laser beam to pass through. The cold plate and the plume removal device may be mounted on the same frame that is disposed over and separate from the stage holding the substrate. FIGS. 17-18 show an example configuration of apparatus with the plume removal device that includes the cold plate. The window may be a cut-out configured to allow the laser beam through. The window may be configured to allow the organic matter ablated by the laser beam to pass though towards the plume removal device.

The apparatus may include a heat shield disposed over a stage configured to hold the substrate, where the heat shield includes window configured to allow the laser beam to pass through. FIGS. 17-18 show an example plume removal device of the apparatus that includes a top heat shield and a bottom heat shield. The window of the heat shield may be configured to allow the organic matter ablated by the laser beam to pass though towards the plume removal device. That is, the window of the heat shield may be configured to allow the plume removal device to be in fluid communication with the plume and the substrate. The heat shield and the plume removal device may be mounted on the same frame that is disposed over and separate from the stage holding the substrate. The window may include a cut-out configured to allow the laser beam through. The window may be configured to allow the organic matter ablated by the laser beam to pass though towards the plume removal device.

The apparatus may include a plurality of channels that are connected to at least one exhaust aperture slot of the plume removal device. In some embodiments, the apparatus may include a plurality of channels that are connected to a plurality of exhaust aperture slots of the plume removal device, where the plurality of exhaust aperture slots is connected radially. In some embodiments, such as shown in FIG. 17, the plume removal device may include a delivery gland to introduce the inert gas into the chamber, and an exhaust gland to remove the inert gas and ablated material from the chamber.

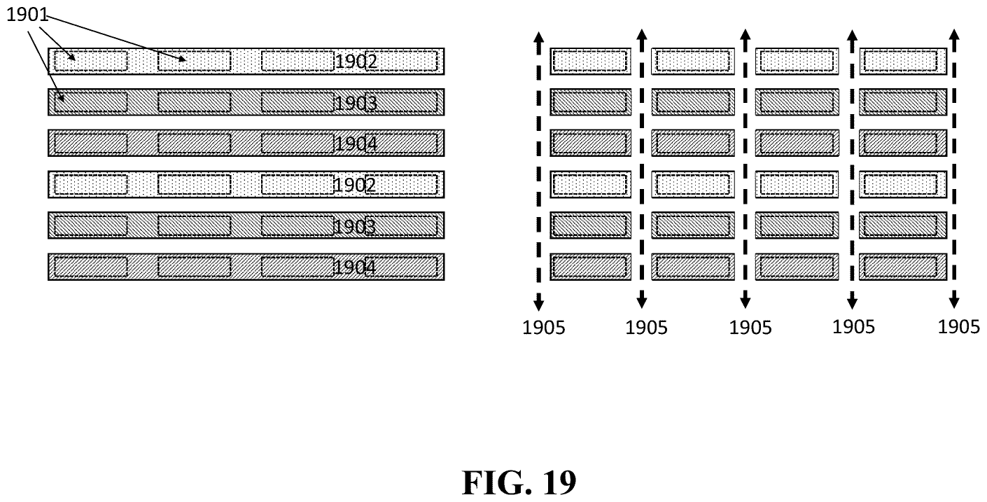

In an embodiment, the laser thin film removal process may be deployed to separate lines printed by OVJP into discrete pixels as shown in FIG. 19. It depicts a display backplane with electrodes 1901 such that each electrode may correspond to a different subpixel. The electrodes may be printed over with blue 1902, green 1903, and red 1904 lines of printed emissive layer extending between pixels to cover neighboring subpixels of the same color. In an embodiment, the emissive layer color combinations may be any colors and/or any color combination. For example, as shown here the lines are blue (B), green (G), and red (R), which then repeat. Alternatively, the lines may be BGBG, BGRGB, BBGR, or any other combination of printed lines. The array on the left side may be before laser thin film removal, and the array on the right side may be after laser thin film removal of at least portions of the emissive layer. A series of laser ablations, performed by plume removal device 103, may cut across 1905 the printed lines between pixels so that the printed thin film covering each electrode is disconnected from its neighbors. Each subpixel may be surrounded on all sides by a perimeter of unprinted backplane. Here, such an architecture may be advantageous because it promotes adhesion of thin film encapsulant to the substrate by creating clean attachment points between electrically active subpixels. In an embodiment, as shown, each electrode and their associated remaining emissive layer may be isolated from any others. In an alternative embodiment, electrodes and their associated remaining emissive layer may be connected to other emissive layers, not shown. In other words, plume removal device 103 may remove emissive layers in some locations but not emissive layers in other locations, so that each emissive layer that is now a smaller portion is not necessarily only located above a single electrode.

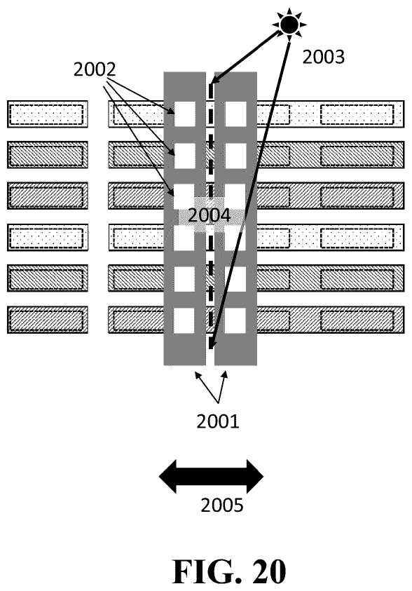

An embodiment of the plume removal system for this application is depicted in FIG. 20. In this embodiment, one or more bar shaped plume removal devices 2001 are depicted. A pair of plume removal devices is depicted here, although other configurations are possible. The devices may each have a linear array of exhaust apertures 2002 facing the substrate and may be configured to optimize removal of the vapor plume generated by the ablated material from each printed line. A laser beam 2003 may scan along the length 2004 of the bar(s), crossing each printed line as it scans. The laser is depicted as scanning a gap between the two bars, although other positions are possible for the laser as well. The laser beam may scan at a steady rate or dwell over each segment of line to be ablated. The plume removal devices may move relative to the substrate in the same direction 2005 as line printing by the OVJP process, permitting the two processes to be placed in-line.

It is understood that the various embodiments described herein are by way of example only, and are not intended to limit the scope of the invention. For example, many of the materials and structures described herein may be substituted with other materials and structures without deviating from the spirit of the invention. The present invention as claimed may therefore include variations from the particular examples and preferred embodiments described herein, as will be apparent to one of skill in the art. It is understood that various theories as to why the invention works are not intended to be limiting.

1. An apparatus comprising:
a laser source configured to output a laser beam;
a beam transfer cavity to receive the outputted laser beam on a first side of the apparatus and output the laser beam on a second side of the apparatus, wherein the first side is opposite the second side; and
a plume removal device having an exhaust aperture on the second side of the apparatus facing a heat affected zone (HAZ).

2. The apparatus of claim 1, wherein the beam transfer cavity is filled with an optically transparent material.

3. The apparatus of claim 2, wherein the optically transparent material is comprised of a sapphire material.

4. The apparatus of claim 1, wherein a bottom surface of the plume removal device is facing a substrate, wherein organic matter is disposed on the substrate, and the HAZ is aligned with the surface of the substrate having the organic matter to be ablated by the laser beam.

5. (canceled)

6. The apparatus of claim 4, wherein the apparatus is disposed in a vacuum chamber having an inert gas at a pressure level that is controlled by a controller.

7. The apparatus of claim 6, wherein the plume removal device comprises an internal microchannel network configured to extract organic vapor formed from ablation by the laser beam with a flow of the inert gas of the chamber.

8. The apparatus of claim 6, further comprising:
an exhaust source in fluid communication with an exhaust channel that is configured to remove the inert gas and ablated material from the chamber.

9. (canceled)

10. The apparatus of claim 8, wherein the plume removal device is configured to have a radially incoming flow of the inert gas from the chamber towards an exit aperture of the plume removal device.

11. The apparatus of claim 6, wherein the plume removal device is disposed at the predetermined distance from the substrate and is configured to induce the flow of the inert gas of the chamber along a plane of the substrate.

12. The apparatus of claim 4, further comprising:
a cold plate disposed over a stage configured to hold the substrate,
wherein the cold plate includes window configured to allow the laser beam to pass through.

13. The apparatus of claim 12, wherein the cold plate and the plume removal device are mounted on the same frame that is disposed over and separate from the stage holding the substrate.

14. The apparatus of claim 12, wherein the window comprises a cut-out configured to allow the laser beam through and is configured to allow the organic matter ablated by the laser beam to pass though towards the plume removal device.

15. The apparatus of claim 4, further comprising:
a heat shield disposed over a stage configured to hold the substrate,
wherein the heat shield includes window configured to allow the laser beam to pass through, and
wherein the window of the heat shield is configured to allow the organic matter ablated by the laser beam to pass though towards the plume removal device.

16. The apparatus of claim 15, wherein the heat shield and the plume removal device are mounted on the same frame that is disposed over and separate from the stage holding the substrate.

17. The apparatus of claim 15, wherein the window comprises a cut-out configured to allow the laser beam through, and is configured to allow the organic matter ablated by the laser beam to pass though towards the plume removal device.

18. The apparatus of claim 4, wherein a fly height between a bottom surface of the plume removal device and the organic matter is 50 μm to 1 mm.

19. The apparatus of claim 4, further comprising:
a sensor configured to detect changes in a surface height of the organic matter disposed on the substrate; and
a controller to control a fly height between a bottom surface of the plume removal device and the organic matter based on the detected changes.

20. The apparatus of claim 4, wherein the substrate is disposed on a stage, and wherein the stage is spaced apart from the laser source.

21-25. (canceled)

26. The apparatus of claim 1, further comprising:
a plurality of channels that are connected to at least one exhaust aperture slot of the plume removal device.

27. The apparatus of claim 1, further comprising a plurality of channels that are connected to a plurality of exhaust aperture slots of the plume removal device, wherein the plurality of exhaust aperture slots is connected radially.

28-30. (canceled)
